(19) United States
(12) Patent Application Publication
(10) Pub. No.: US 2026/0331145 A1
(43) Pub. Date: Oct. 22, 2026

(54) APPARATUS WITH WORD LINES AND WORD LINE CONTACTS

(71) Applicant: Micron Technology, Inc., Boise, ID (US)

(72) Inventor: Takashi Sasaki, Higashihiroshima (JP)

(21) Appl. No.: 19/650,820

(22) Filed: Apr. 17, 2026

Related U.S. Application Data
(60) Provisional application No. 63/792,548, filed on Apr. 22, 2025.

(51) Int. Cl. G11C 5/06; H10W 10/17; H10W 10/40; H10W 20/43

(52) U.S. Cl. CPC G11C 5/063; H10W 10/17; H10W 10/40; H10W 20/43

(57) ABSTRACT

Some embodiments of the disclosure provides an apparatus comprising: a word line contact coupled to one of neighboring word lines; and a block pad located between the neighboring word lines and configured to block the word line contact from coupling to another of the neighboring word lines. The word line contact and the block pad may be in a peripheral region adjacent to a memory cell array region. The block pad may include polysilicon. The block pad may be embedded in a shallow trench isolation formed in a semiconductor substrate. Even if the word line contact is misaligned from its associated word line, the word line contact remains distant from the neighboring word line because of the block pad between the two word lines. This effectively prevents a word line-to-word line short circuit and achieves a higher-quality memory device.

### CROSS-REFERENCE TO RELATED APPLICATIONS

This application claims the filing benefit of U.S. Provisional Application No. 63/792,548, filed Apr. 22, 2025. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit lines arranged in columns. Memory cells may include capacitors for data storage and transistors for accessing the capacitor. Word lines may serve as gates or gate terminals of access transistors. Word lines may be coupled to word line contacts.

### BRIEF DESCRIPTION OF THE DRAWINGS

FIG. 1A depicts an example layout of memory mats in a memory device in a plan view, and FIG. 1B depicts an example memory mat in an enlarged view, according to some embodiments of the disclosure.

FIGS. 2A and 2B depict at least part of an example memory device in areas A and B shown in FIG. 1B, respectively, according to some embodiments of the disclosure.

FIGS. 3A-3C-11A-11C depict example processes of forming at least part of a memory device in a plan view and a cross-sectional view according to some embodiments of the disclosure.

FIG. 12 is a block diagram of an example semiconductor device according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

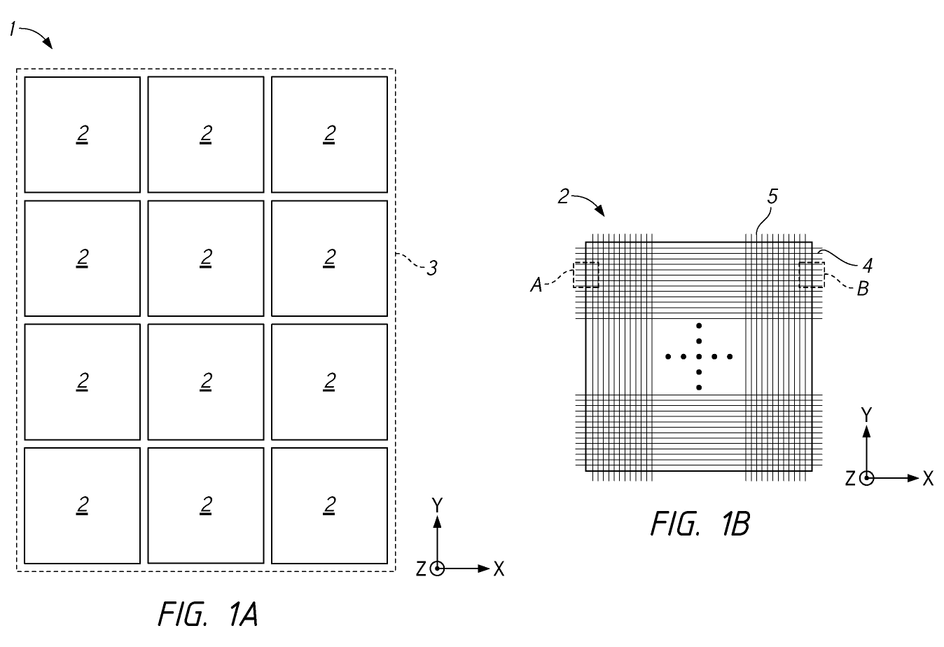

FIG. 1A depicts an example layout of memory mats 2 in a memory device 1 in a plan view according to some embodiments of the disclosure. FIG. 1B depicts an example memory mat 2 in an enlarged view according to some embodiments of the disclosure. The memory device 1 may be one example of a semiconductor device. The memory device 1 may be one example of an apparatus. The memory device 1 may be a DRAM. The memory device 1 includes a plurality of memory mats 2 arranged in a matrix on a semiconductor substrate 3. Each memory mat 2 includes a plurality of word lines 4 and a plurality of bit lines 5 in a memory cell array region. Word lines 4 are arranged in rows, each extend in a first horizontal direction, which may be an X-axis direction in the drawing, and positioned in parallel with each other in a second horizontal direction, which may be a Y-axis direction in the drawing, perpendicular (or substantially perpendicular within reasonable tolerances of fabrication, measurement, etc.) to the first horizontal direction. Bit lines 5 are arranged in columns, each extend in the Y-axis direction and positioned in parallel with each other in the X-axis direction. The word lines 4 and the bit lines 5 are orthogonal to each other. Each memory mat 2 may include a plurality of memory cells at intersections of the word lines 4 (rows) and the bit lines 5 (columns). A direction parallel to the word lines 4 may be referred to as a word-line direction. A direction parallel to the bit lines 5 may be referred to as a bit-line direction. The word lines 4 extend through the memory mat 2 into a peripheral region adjacent to a memory cell array region in the X-axis/word-line direction. The bit lines 5 extend through the memory mat 2 into a peripheral region adjacent to the memory cell array region in the Y-axis/bit-line direction. In the peripheral region in the word-line direction, the word lines 4 may be coupled to peripheral circuits, such as a row decoder. For example, at the time of reading data from or writing data to a memory cell, a selected row address may be input to a row decoder from a row address buffer, and a word line of the selected row may control access to one or more corresponding memory cells. In the peripheral region in the bit-line direction, the bit lines 5 may be coupled to other peripheral circuits, such as a column decoder. For example, at the time of data read or data write, a selected column address may be input to a column decoder from a column address buffer, and a bit line of the selected column may control access to one or more corresponding memory cells.

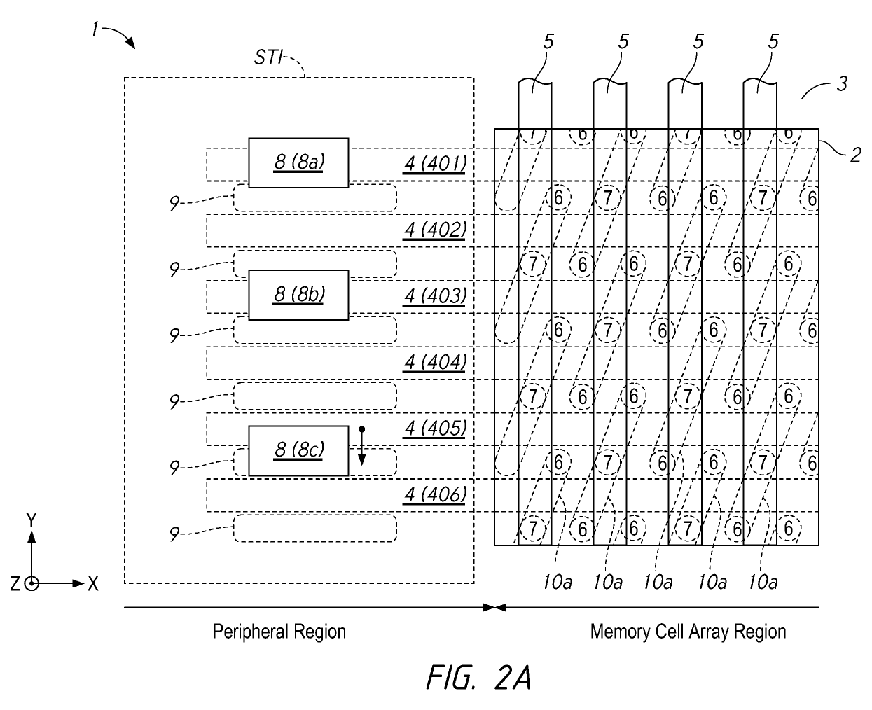

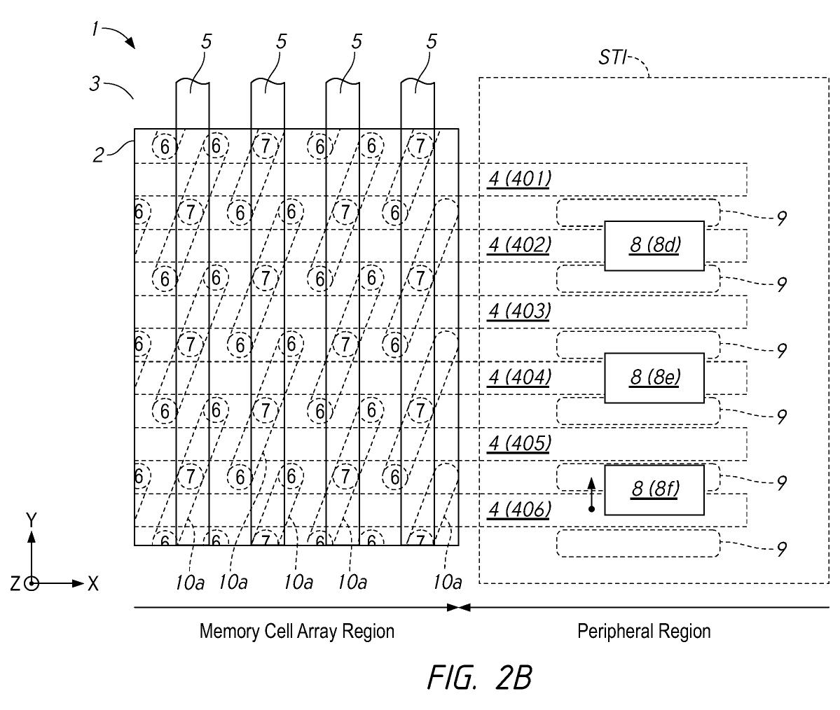

FIGS. 2A and 2B depict at least part of the example memory device 1 in areas A and B shown in FIG. 1B, respectively, according to some embodiments of the disclosure. The areas A and B are located at one end and another end of the memory mat 2 in the X-axis/word-line direction, respectively, as shown in FIG. 1B.

Referring to FIG. 2A, the memory device 1 includes a memory cell array region and a peripheral region. The memory cell array region may have a shape corresponding to a shape of the memory mat 2, for example a square shape, a rectangular shape, or the like, in the plan view on the semiconductor substrate 3. The peripheral region may be provided around the periphery of the memory cell array region in the plan view on the semiconductor substrate 3. In the memory cell array region, a plurality of word lines 4 are arranged at regular pitches in the Y-axis/word-line direction, and a plurality of bit lines 5 are arranged at regular pitches in the X-axis/bit-line direction. The word lines 4 and the bit lines 5 are orthogonal to each other. At intersections of the word lines 4 and the bit lines 5, a plurality of active regions 10a forming at least part of the memory cell are arranged. The longitudinal direction of the active regions 10a is inclined by a predetermined angle with respect to the bit lines 5. The word lines 4 serve as gate electrodes of access transistors of memory cells provided to the active regions 10a. The bit lines 5 are coupled to the active regions 10a via bit line contacts 7. In each active region 10a, a capacitive contact 6 is arranged on a side opposite to the corresponding bit line contact 7 of the bit line 5. To each capacitive contact 6, a memory cell capacitor (not separately depicted) is coupled. The capacitive contact 6 may also be referred to as a cell contact.

The word lines 4 linearly extend across the memory cell array region into the peripheral region. In the peripheral region, word line contacts 8 are coupled to the associated word lines 4. In the depicted example, the word line contacts 8 are coupled to alternate ones of the word lines 4, which are odd-numbered word lines 401, 403, and 405 in FIG. 2A. The word line contacts 8 are not provided to the other alternative word lines 4, which are even-numbered word lines 402, 404, and 406 in FIG. 2A. In the peripheral region, peripheral circuits, such as a row decoder and a row address buffer, may be provided. The word lines 4 (401, 403, and 405) may be coupled to the peripheral circuits via the word line contacts 8.

Referring to FIG. 2B, in the area B at the opposite end of the memory mat 2 from the area A, the word lines 4 extend into the peripheral region from the memory cell array region in the X-axis/word-line direction, similarly to those in the area A. Unlike the area A, however, the word line contacts 8 are provided to the even-numbered word lines 402, 404, and 406, not to the odd-numbered word lines 401, 403, and 405. Other than the arrangement of the word line contacts 8, the configuration in the area B shown in FIG. 2B is substantially the same as the configuration in the area A shown in FIG. 2A.

In the depicted example according to the present embodiments, in both areas A and B, a shallow trench isolation STI is provided in the semiconductor substrate 3 in the peripheral region. The shallow trench isolation STI is located adjacent to the memory cell array region. The shallow trench isolation STI may isolate structures, components, or the like provided in the cell array region from structures, components, or the like provided in the peripheral region. The shallow trench isolation STI may include an insulating material, such as silicon oxide (SiO₂ or simply SiO).

Furthermore, a plurality of block pads 9 are provided in the peripheral region. Each block pad 9 is located between neighboring word lines 4. The block pad 9 may be embedded in the shallow trench isolation STI. The block pad 9 may be formed in an upper portion of the shallow trench isolation STI. The block pad 9 may include an insulating material different from the insulating material of the shallow trench isolation STI. The block pad 9 may include polycrystalline silicon or polysilicon. The block pad 9 may have a pad-like shape with a certain depth in a vertical direction (e.g., a Z-axis direction in the drawing) into the shallow trench isolation STI and a certain length elongated in the word-line direction between the neighboring word lines 4. The block pad 9 may be adjacent to the word line contact 8 and partially under the word line contact 8. The block pad 9 may be configured to prevent coupling of the corresponding word line contact 8 to one of the neighboring word lines 4. The block pad 9 may be configured to block the word line contact 8 from coming into contact with a conductive part of the neighboring word line 4. For example, the peripheral region may include a layered structure above the word line 4, having multiple layers including but are not limited to an oxide layer, a nitride layer, or the like stacked in the vertical direction (e.g., the Z-axis direction in the drawing). The word line contact 8 extends through the layered structure in the Z-axis direction and reaches at least a conductive part, such as a metal part, of the associated word line 4. The word line contact 8 is aligned with the associated word line 4. For example, the word line contact 8 may have its center aligned or substantially aligned to the center of the associated word line 4 in the Y-axis direction in the drawing, that is the direction of the width of the word line 4 or the pitch between the word lines 4. The block pad 9 is provided between the neighboring word lines 4 and adjacent to the word line contact 8. In the case where the word line contact 8 is misaligned during its formation as part of device fabrication, the word line contact 8 may be displaced toward the other word line 4 from the associated word line 4. As finer geometries are demanded, a repeating pitch of word lines 4 and/or a distance between neighboring word lines 4 may be reduced. If misalignment occurs, the word line contact 8 may come into contact with the other, non-associated word line 4, which may cause a short circuit. In such a case, however, in the present embodiments, the block pad 9 may block the misaligned word line 4 from coming into contact with at least a conductive part of the other word line 4, preventing a word line-to-word line short. As one example in FIG. 2A, the word line contact 8a is aligned with and coupled to the word line 401, and the block pad 9 is provided between the contact-coupled word line 401 and its neighboring word line 402. The next word line contact 8b is aligned with and coupled to the word line 403, and the block pad 9 is provided between the word line 403 and its neighboring word line 402 on one side of the word line contact 8b. Another block pad 9 is provided between the word line 403 and another neighboring word line 404 on the other side. The word line contacts 8a and 8b are properly aligned with the associated word lines 401 and 403, respectively. On the other hand, the next word line contact 8c is misaligned from the associated word line 405 and displaced toward the neighboring word line 406. This word line 406 is not associated with the word line contact 8c. The word line contact 8c is not supposed to couple to the word line 406. Even in such a misalignment case, the misaligned word line contact 8c does not come into contact with, or does not come too close to, the word line 406 because of the block pad 9 positioned between the word lines 405 and 406. This effectively prevents a short circuit. Similarly, as shown in FIG. 2B, while the word line contacts 8d and 8e are properly aligned with their respective associated word lines 402 and 404, the word line contact 8f is not aligned with its associated word line 406 and displaced toward the neighboring, non-associated word line 405. Even in this situation, the word line contact 8f does not come into contact with, or does not come too close to, the word line 405 because of the block pad 9 between the word lines 405 and 406, thereby preventing a short circuit with the word line 405. Therefore, according to the present embodiments, even if a word line contact is misaligned from its associated word line, the misaligned word line contact, and hence its associated word line, does not cause a short circuit with a neighboring, non-associated word line. As a result, a memory device of higher quality can be achieved. In some instances, the block pad 9 may not necessarily have a pad-like shape so long as it blocks the word line contact from coupling to a non-associated word line and prevents a word line-to-word line short circuit. The block pad 9 may thus simply be a block part or a blocking part for a misaligned word line contact in the word line contact area within the peripheral region. When the block pad 9 includes polysilicon, it may be referred to as a polysilicon pad or a polysilicon block part. The block pad 9 may include other insulating materials as appropriate.

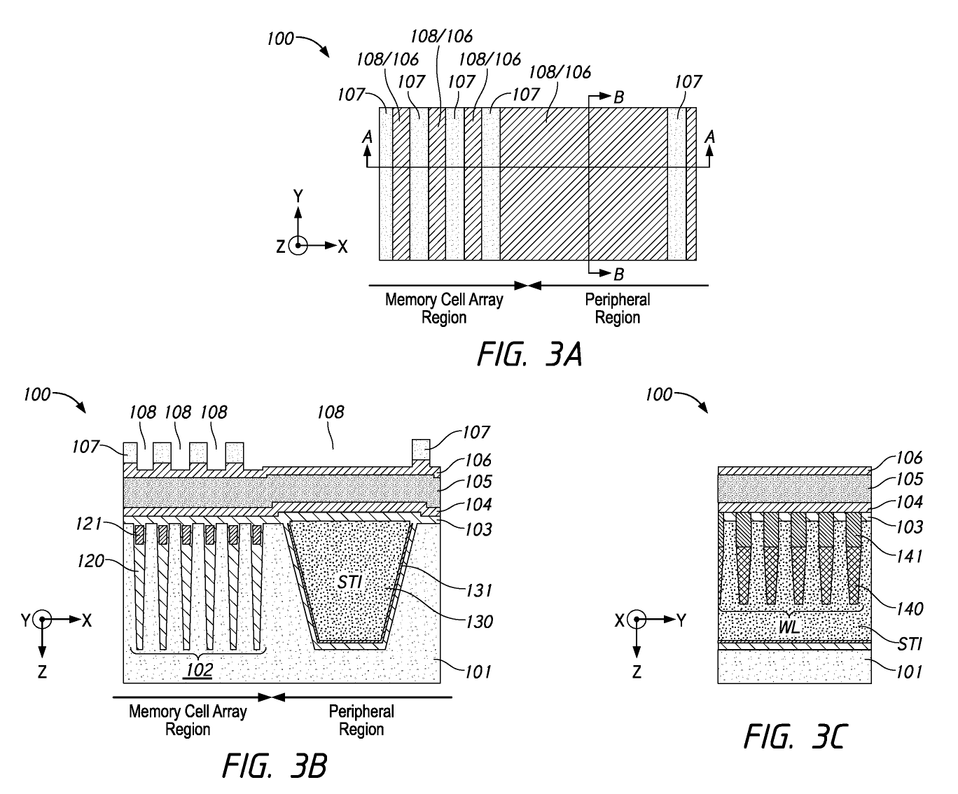

FIGS. 3A-3C-10A-10C depict example processes of forming at least part of a memory device 100 in a plan view and a cross-sectional view according to some embodiments of the disclosure. FIGS. 3A-10A depict the processes in the plan view. The cross-sectional views in FIGS. 3B-10B correspond to line A-A in FIGS. 3A-10A. The cross-sectional views in FIGS. 3C-10C correspond to line B-B in FIGS. 3A-10A. The memory device 100 may correspond to the memory device 1 of FIG. 1A and FIGS. 2A-2B. The memory device 100 includes a memory cell array region and a peripheral region adjacent to the memory cell array region. The memory cell array region and the peripheral region may correspond to those in FIGS. 2A and 2B, respectively. An example method to form at least part of a memory device according to some embodiments of the disclosure may include the processes described below.

First, as shown in FIGS. 3A-3C, a part of the memory device 100 is formed, including, for example, a plurality of word lines WL, a plurality of isolations 102, and a shallow trench isolation STI formed in a semiconductor substrate 101, such as a silicon substrate. The word lines WL are formed at certain positions, each extending across the memory cell array region and the peripheral region in the X-axis direction and arranged in parallel with each other in the Y-axis direction. Each word line WL may include a lower conductive part 140 and an upper insulating part 141. The lower conductive part 140 may include a conductive material, such as a metal. The upper insulating part 141 may include an insulating material. In the depicted example, a top portion of the insulating part 141 penetrates a certain layer provided on the semiconductor substrate 101 and reaches another layer above the semiconductor substrate 101, such as an oxide layer 103 and an ARC layer 104 (which will be further described below). The configuration of the word line WL is not limited to the depicted example. There may be other layers, films, or the like included in the word line structure. Any conventional methods/processes may be applicable to form the word line structure as appropriate.

Each isolation 102 formed in the memory cell array region may have a structure configured to isolate neighboring diffusion layers or diffused regions of the semiconductor substrate 101. The isolation 102 may include a lower part 120 that includes an insulating material such as silicon oxide (SiO₂ or simply SiO) and an upper part 121 that includes a different insulating material such as silicon nitride (Si₃N₄ or simply SiN). The shallow trench isolation STI formed in the peripheral region may be configured to isolate structures, components, or the like in the memory cell array region from structures, components, or the like in the peripheral region. The shallow trench isolation STI may include an insulating material 130, such as SiO. The shallow trench isolation STI may further include another insulating material 131, such as SiN on its side portions. The isolation 102 and the shallow trench isolation STI may be formed by, for example, forming trenches in the semiconductor substrate 101 and embedding insulating materials in the trenches. The configurations of the isolation 102 and the shallow trench isolation STI are not limited to the depicted example. There may be other layers, films, or the like included in the isolation 102 and the shallow trench isolation STI. Any conventional methods/processes may be applicable to form the isolation 102 and the shallow trench isolation STI in the semiconductor substrate 101 as appropriate.

The memory device 100 further includes a mask oxide layer 103, an anti-reflective coating (ARC) layer 104, a carbon layer 105, another ARC layer 106, and another oxide layer 107 stacked in that order, forming the layered structure on the semiconductor substrate 101. In the depicted example, a top surface of the shallow trench isolation STI in the peripheral region is slightly higher than a top surface of the isolations 102 in the memory cell array region. The layered structure in the peripheral region therefore has a raised portion or a step portion corresponding to the profile of the shallow trench isolation STI. After the layered structure is formed on the semiconductor substrate 101, the upper ARC layer 106 and the upper oxide layer 107 are patterned to form a line-and-space pattern with lines extending in parallel with one another in one horizontal direction (the X-axis direction in the drawing) and spaces or openings 108 between neighboring lines. The respective openings 108 will be used to provide a plurality of polysilicon parts at a later process. Each opening 108 penetrates through the oxide layer 107 and extends midway into the upper ARC layer 106. The position and size of the line-and-space pattern may be predetermined to correspond to the to-be-formed polysilicon parts. Any conventional processes, such as deposition, polishing, etching, and photolithography, and conventional materials may be applicable to form the layered structure and the patterns as appropriate.

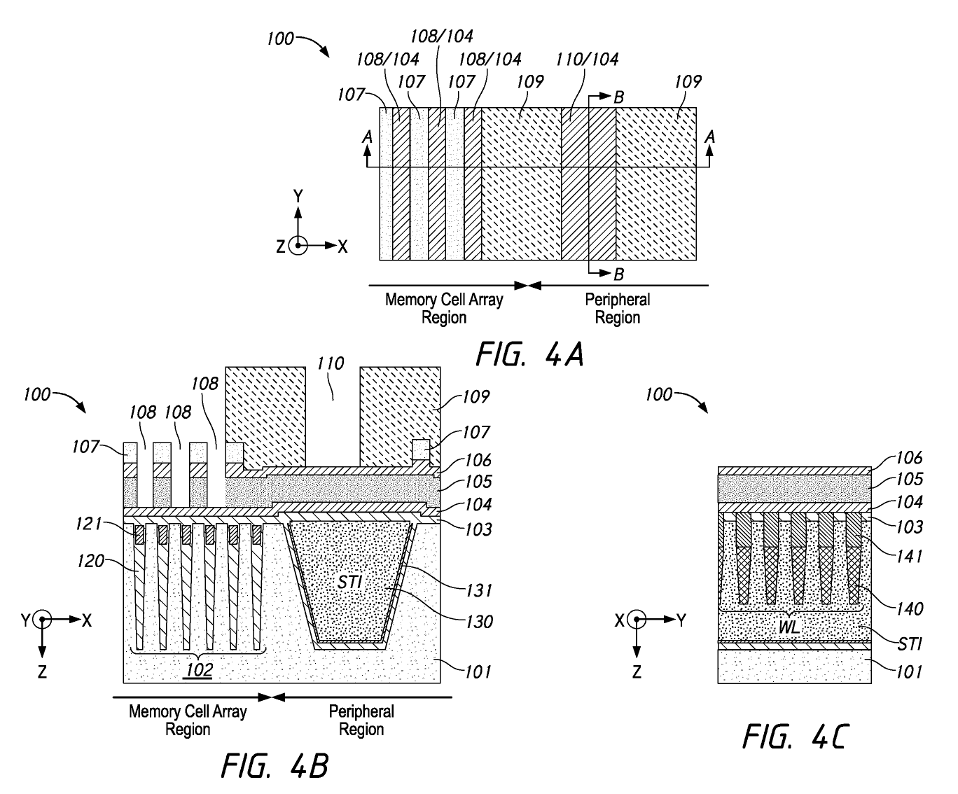

Next, as shown in FIGS. 4C-10A-10C A- 4 C, a photoresist 109 is provided on the exposed surface of the layered structure at least in the peripheral region. In the depicted example, the photoresist 109 is also provided on at least part of the exposed surface of the layered structure in the memory cell array region. The photoresist 109 is initially continuous from the peripheral region to the adjacent part of the memory cell array region. The photoresist 109 covers the area that needs to be protected from later processes, such as etching and patterning, that are primarily aimed at certain areas of the memory cell array region. The trench-like or groove-like openings 108 in the memory cell array region are then further extended by, for example, dry or wet etching to penetrate the upper ARC layer 106 and the carbon layer 105, reaching the lower ARC layer 104. In the peripheral region, the photoresist 109 is patterned to form an opening 110, which exposes the underlying upper ARC layer 106, at the location where the polysilicon part will be formed. The patterning may be performed by conventional processes, such as photolithography and etching.

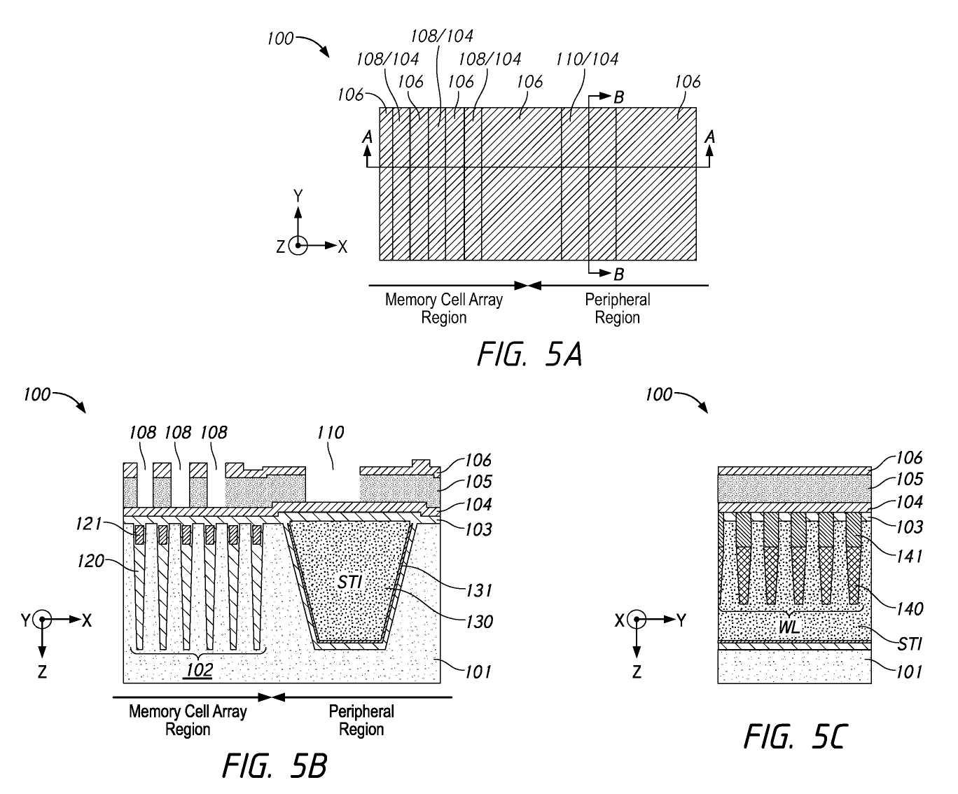

Subsequently, as shown in FIGS. 5A-5C, in the peripheral region, part of the upper ARC layer 106 and part of the carbon layer 105 are removed through the opening 110, by for example etching, exposing the lower ARC layer 104. The photoresist 109 and the upper oxide layer 107 are then removed.

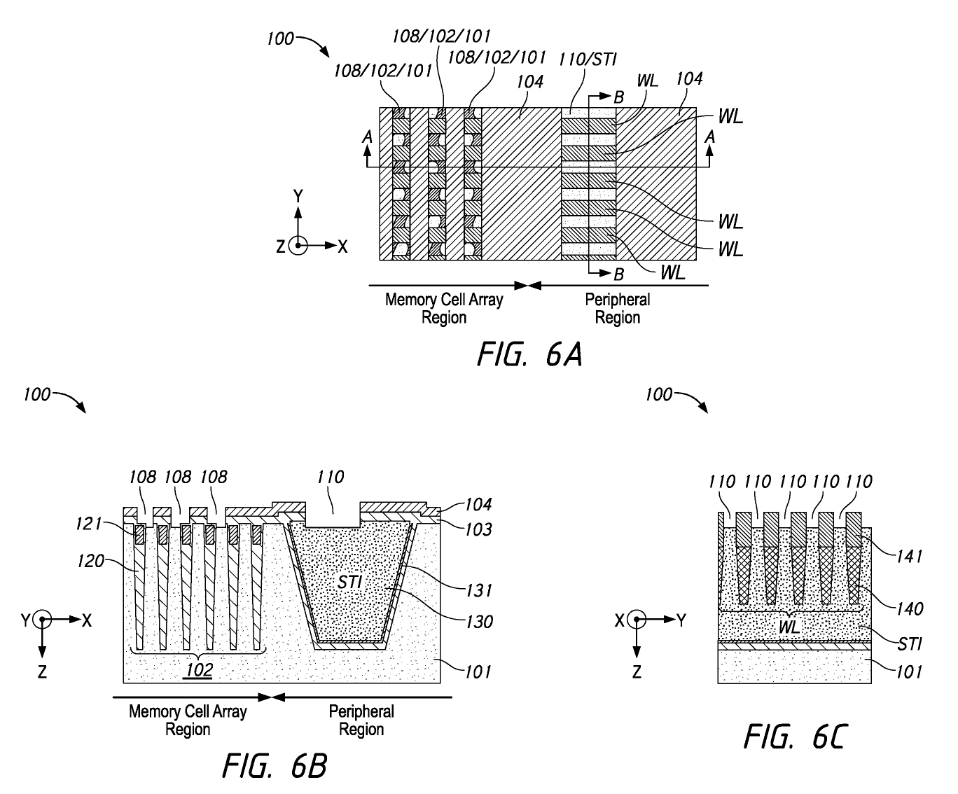

As shown in FIGS. 6A-6C, part of the lower ARC layer 104 and part of the lower oxide layer 103 in the memory cell array region are removed through the openings 108, and part of the lower ARC layer 104 and part of the lower oxide layer 103 in the peripheral region are removed through the opening 110. Furthermore, the underlying portion of the semiconductor substrate 101 in the memory cell array region and the underlying portion of the shallow trench isolation STI in the peripheral region are removed. In the peripheral region, this removal reveals the word lines WL in the removed portions of the oxide layer 103 and ARC layer 104. The opening 110 extends into an upper portion of the shallow trench isolation STI. Also, the opening 110 now further extends between the neighboring word lines WL in the Z-axis direction as shown in FIG. 6C, making a plurality of trench-like or groove-like openings next to the respective word lines WL. Afterwards, the remaining portions of the upper ARC layer 106 and the carbon layer 105 are removed. These removal processes may be performed by, for example, etching. Other processes, such as cleaning, may also be applied as appropriate. The amount of the removal may be adjusted by, for example, determining etching conditions (e.g., etchant, etching rate, etching time, and the like) so that the resultant spaces/openings each have an appropriate size including depth and width for the polysilicon part to be formed therein at the following steps.

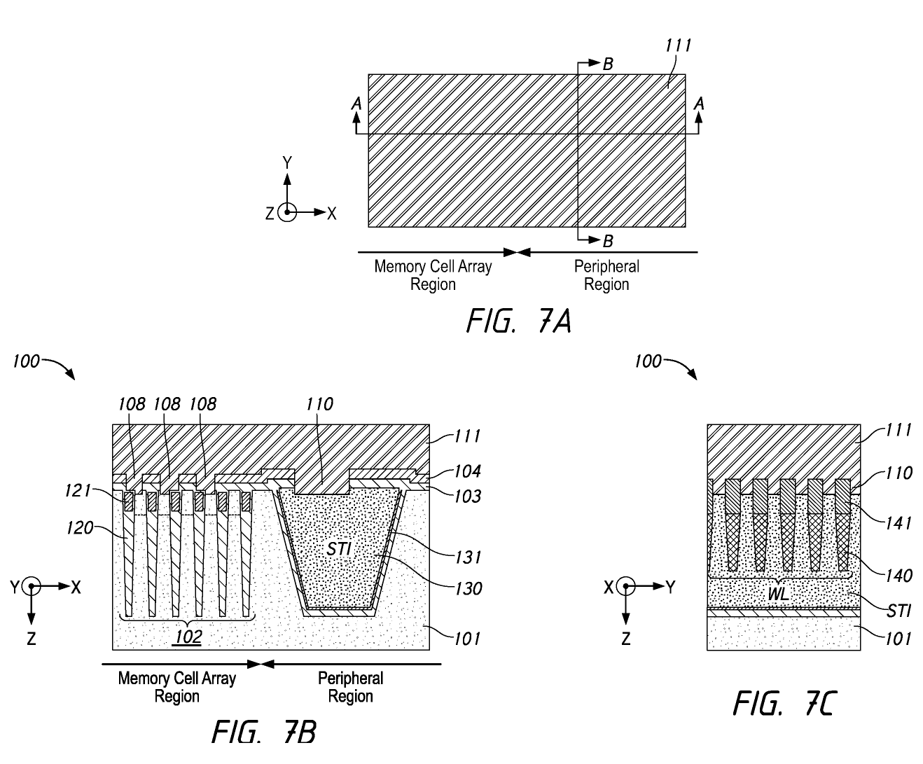

To form the polysilicon part, first, as shown in FIGS. 7A-7C, a polycrystalline silicon or polysilicon (poly-Si) layer 111 is provided on the exposed surfaces of the resultant structure of the foregoing process. More specifically, for example, the exposed surfaces are first cleaned, and then poly-Si is deposited across the memory cell array region and the peripheral region to at least fill the openings 108 and the openings 110.

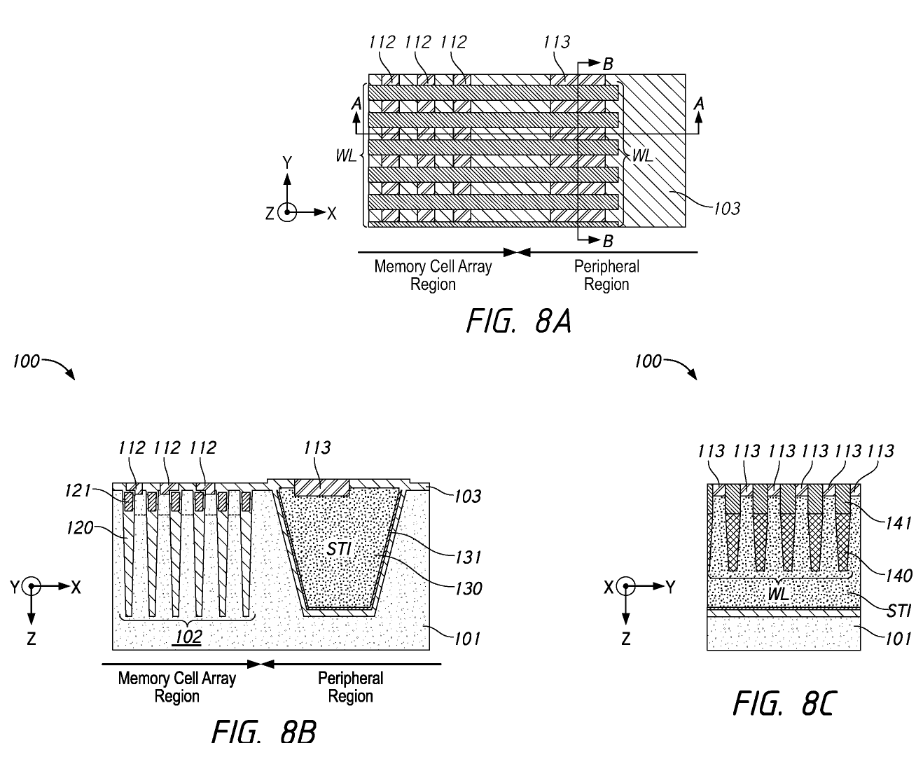

As the next step of the polysilicon part formation, as shown in FIGS. 8A-8C, the poly-Si layer 111 and the underlying ARC layer 104 are removed by, for example, etching while leaving the poly-Si in the openings 108 and the openings 110. A top portion of the oxide layer 103 under the ARC layer 104 may also be slightly removed as a result of etching. The etching conditions may be appropriately adjusted so that the poly-Si 101 remains only in the openings 108 and the openings 110. This forms polysilicon parts 112 and 113 in the memory cell array region and the peripheral region, respectively. The polysilicon parts 112 in the memory cell array region are on the associated insulations 102 and separate neighboring insulations 102 from each other. The polysilicon parts 113 in the peripheral region are located between the neighboring word lines WL. Each polysilicon part 113 is embedded in a top portion of the shallow trench isolation STI. In the depicted example, a top part of the polysilicon part 113 protrudes in the oxide layer 103, and a top surface of the polysilicon part 113 is flush with a top surface of the oxide layer 103. The polysilicon part 113 may have a pad-like shape between the neighboring word lines WL with a certain depth into the shallow trench isolation STI and a certain length in the word-line direction. The polysilicon part 113 serves as a structure that blocks a word line contact from contacting or from getting too close to unnecessary conductive parts, such as a conductive portion of a neighboring word line, to prevent a short circuit. This will be described in further detail below.

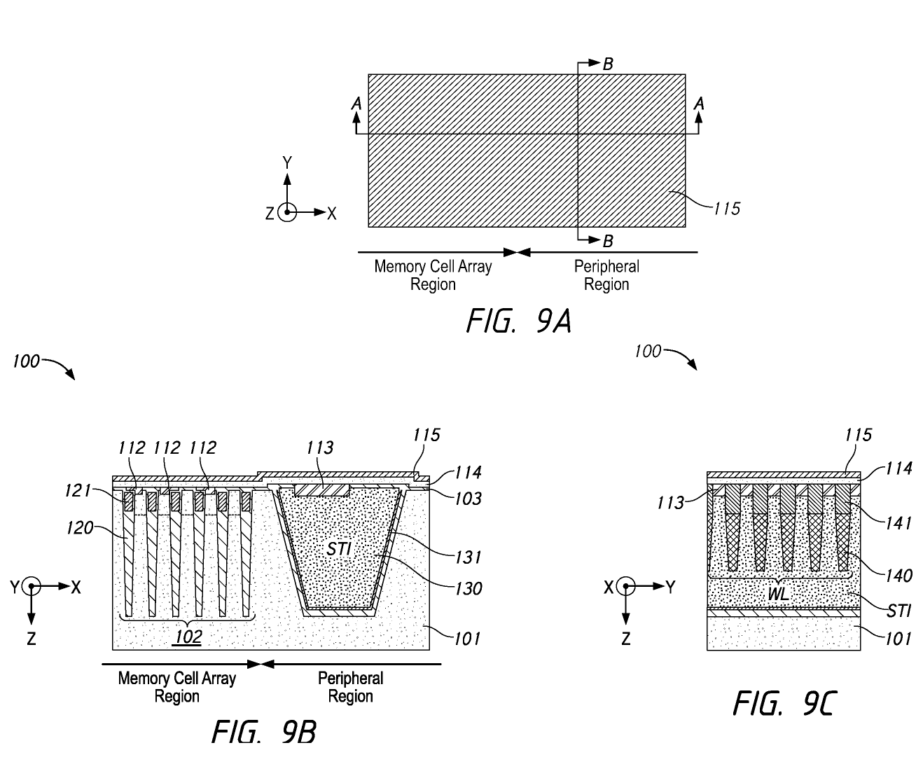

Subsequently, as shown in FIGS. 9A-9C, an oxide layer 114 and a nitride layer 115 are provided by, for example, deposition, across the memory cell array region and the peripheral region to cover the exposed surfaces of the resultant structure of the above process including the polysilicon parts 112 and 113.

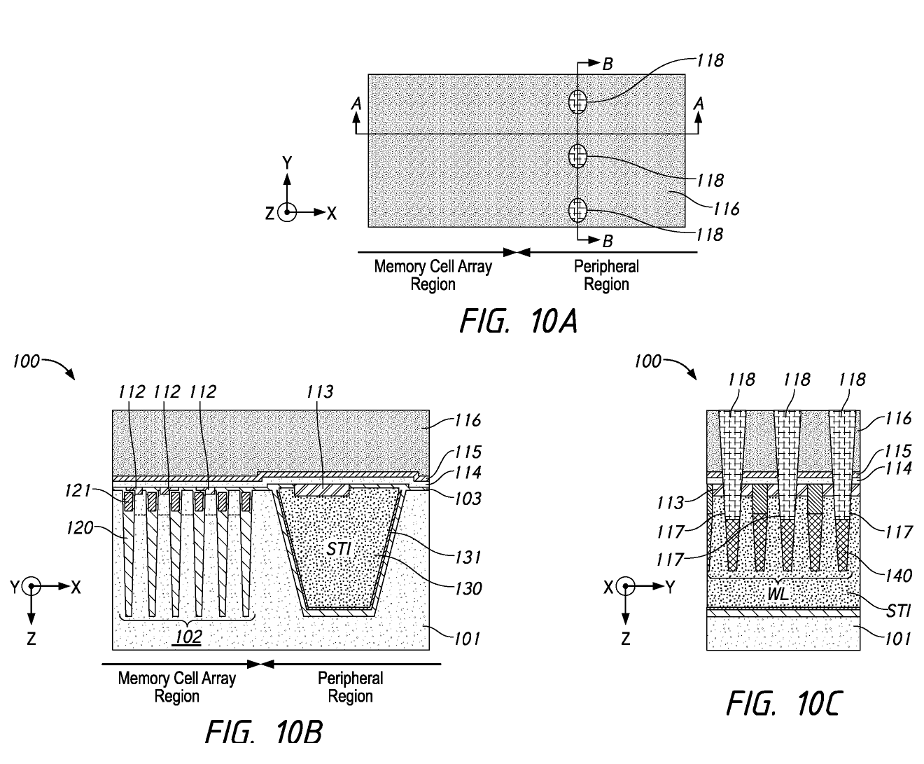

In the peripheral region, as shown in FIGS. 10A-10C, word line contacts 118 are formed on the associated word lines WL, aligned with each other. An oxide layer 116 is first provided on the nitride layer 115 by for example deposition, and trenches 117 are then formed through the oxide layer 116, the nitride layer 115, and the oxide layer 114 by for example etching these layers. The etching further removes the insulating part 141 (see FIG. 9C) of each word line WL so that each trench 117 reaches the underlying conductive part 140 of the associated word line WL. In the depicted example, the trench 117 also extends into an upper portion of the conductive part 140 to ensure coupling thereto. The trenches 117 are then filled with a conductive material such as metal, forming the word line contacts 118. The word line contacts 118 are thus formed on and coupled to the conductive parts 140 of the associated word lines WL. In some instances, each of the word line contact 118 may include a barrier metal, such as titanium (Ti) or titanium nitride (TiN), and the contact metal, such as tungsten (W), on the barrier metal. For example, the barrier metal may be first deposited on side and bottom surfaces of the trench 117, and the contact metal may be then provided on the barrier metal, filling the trench 117. The word line contact 118 and the polysilicon part 113 may be adjacent to each other. The word line contact 118 may be located between the neighboring polysilicon parts 113. The word line contacts 118 may correspond to the word line contacts 8 of FIGS. 2A-2B. Similarly to the word line contacts 8, the word line contacts 118 may be provided to the odd-numbered word lines and the even-numbered word lines at opposite ends, respectively, of a memory mat in the word-line direction (also see FIGS. 1A-1B and 2A-2B). The polysilicon parts 113 may correspond to the block pads 8 of FIGS. 2A-2B.

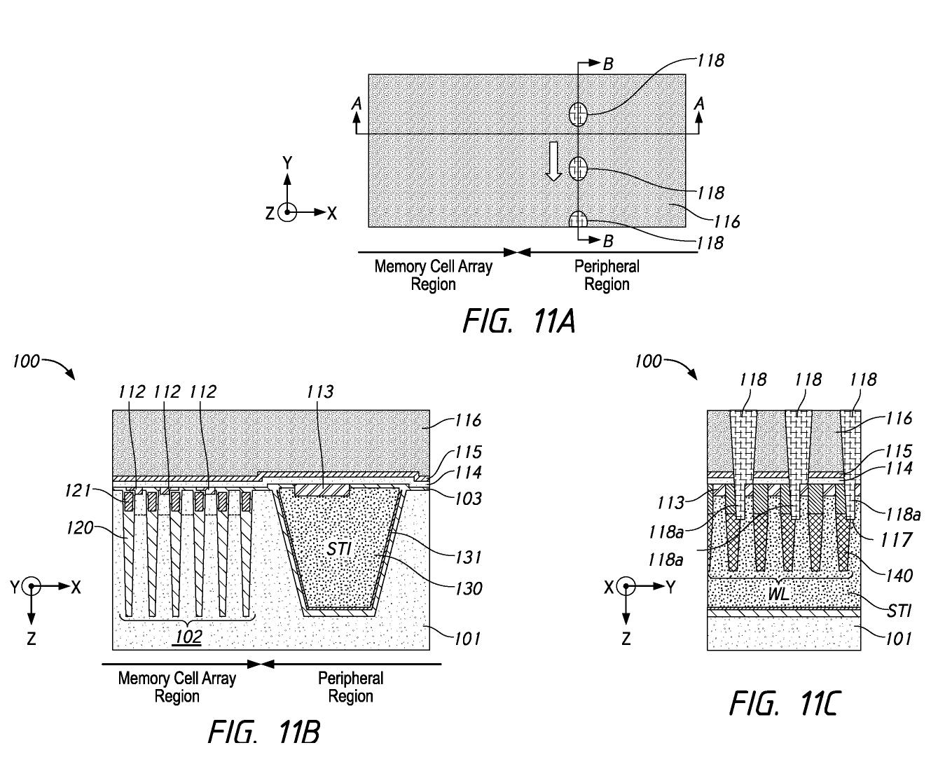

FIGS. 10A-10C described above illustrate the case where the trenches 117, and hence the word line contacts 118, are properly aligned with the respective associated word lines WL so that the word line contacts 118 are not coupled to neighboring, non-associated word lines WL. On the other hand, FIGS. 11A-11C illustrate the case where there is misalignment of the trenches 117 and word line contacts 118 from the respective associated word lines WL. According to the present embodiments, even if misalignment occurs during trench formation (e.g., in the Y-axis direction in the drawing), each polysilicon part 113 blocks further etching and prevents the trench 117 from reaching the conductive part 140 of the neighboring word line WL. Consequently, the word line contact 118 formed in the trench 117 does not come into contact with at least the conductive part 140 of the neighboring word line WL. More specifically, in the depicted example, while the word line contact 118 has a lower part or a lower end 118a, which is not blocked by the polysilicon part 113, reaching the conductive part 140 of the associated word line WL, the lower end 118a does not extend directly underneath the polysilicon part 113 in the vertical direction (the Z-axis direction in FIG. 11C), thereby not coupling to the conductive part 140 of the neighboring word line WL. The word line contact 118 thus remains sufficiently distant from the conductive part 140 of the neighboring word line WL to avoid a short circuit. Accordingly, by adding the polysilicon parts 113 in the word line contact area of the peripheral region, even in cases of trench/contact misalignment, WL-WL shorts are effectively prevented. This can achieve higher-quality memory devices and increased production yields.

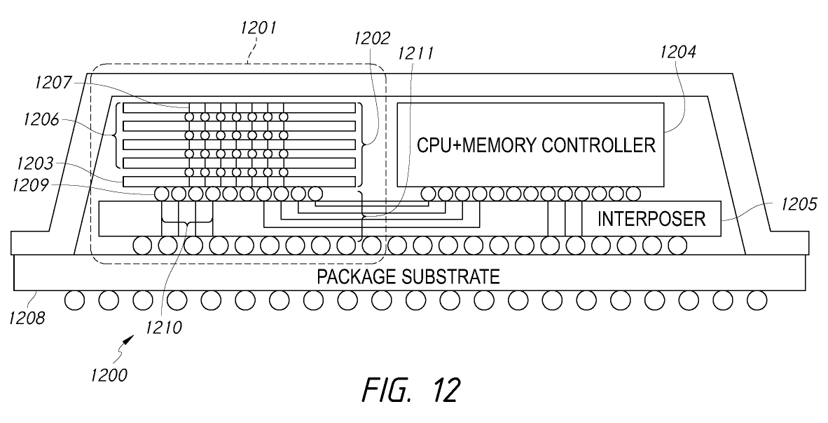

FIG. 12 depicts a schematic configuration of an example semiconductor system 1200 according to some embodiments of the disclosure. The semiconductor system 1200 includes a semiconductor memory device 1201 in an embodiment of the disclosure. In some embodiments of the disclosure, the semiconductor memory device 1201 may include the memory device 1 of FIGS. 1A-1B and 2A-2B or the memory device 100 of FIGS. 3A-1C -11A-11C. The semiconductor system 1200 may also include a central processing unit (CPU) and memory controller 1204, which may be a controller chip, on an interposer 1205 on a package substrate 1208. The interposer 1205 may include one or more power lines 1210 which may supply power supply voltage from the package substrate 1208. The interposer 1205 may include a plurality of channels 1211 that may interconnect the CPU and memory controller 1204 and the semiconductor memory device 1201. The semiconductor memory device 1201 may be a DRAM. The memory controller 1204 may provide a clock signal, a command signal, and may further transmit and receive data signals. The plurality of channels 1211 may transmit the data signals between the memory controller and the memory device 1201.

The semiconductor memory device 1201 may include a plurality of dies (or chips) 1202 including at least one interface (IF) die (or chip) 1203 and a plurality of memory core dies (or chips) 1206 stacked with each other. A number of the memory core dies 1206 may not be limited to four as in the illustrated example, and may be more or fewer as appropriate. Each of the memory core dies 1206 may include a plurality of memory cells and circuitries accessing the memory cells. For example, the memory cells may be DRAM cells. The memory cells may be arranged in array. The semiconductor memory device 1201 may include conductive vias 1207 which couple the IF die 1203 and the memory core dies 1206 by penetrating the IF die 1203 and the memory core dies 1206. The IF die 1203 may be coupled to the interposer 1205 via interconnects 1209. For example, the interconnects 1209 may be microbumps having bump pitches of less than about or less than one hundred micrometers and exposed on an outside of the IF die 1203. A portion of each of the interconnects 1209 may be coupled to the one or more power lines 1210. Another portion of each of the interconnects 1209 may be coupled to one or more of the channels 1211.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a plurality of word lines extending across a memory cell array region into a peripheral region adjacent to the memory cell array region;
a plurality of word line contacts coupled to respective associated word lines of the plurality of word lines in the peripheral region;
a shallow trench isolation in a semiconductor substrate in the peripheral region; and
a plurality of block pads in an upper portion of the shallow trench isolation and adjacent to corresponding word line contacts of the plurality of word line contacts, the plurality of block pads configured to prevent coupling of the corresponding word line contacts to non-associated word lines.

2. The apparatus according to claim 1, wherein the block pads each include an insulating material different from a material of the shallow trench isolation.

3. The apparatus according to claim 2, wherein the block pads each include polysilicon.

4. The apparatus according to claim 1, wherein the block pads block the corresponding word line contacts from coming into contact with conductive parts of the non-associated word lines.

5. The apparatus according to claim 1, wherein the block pads prevent the word line contacts misaligned from the associated word lines from coupling to the non-associated word lines.

6. The apparatus according to claim 5, wherein the block pads make the misaligned word line contacts distant from the non-associated word lines.

7. An apparatus, comprising:
a plurality of word lines and a plurality of word line contacts;
an isolation structure in a semiconductor substrate; and
a block part formed in the isolation structure and located between a first word line and a second word line of the plurality of word lines, the block part configured to prevent a short circuit between a word line contact of the first word line and the second word line.

8. The apparatus according to claim 7, wherein the block part blocks the word line contact of the first word line from reaching the second word line.

9. The apparatus according to claim 8, wherein the word line contact of the first word line is distant from the second word line.

10. The apparatus according to claim 7, wherein the block part includes an insulating material different from a material of the isolation structure.

11. The apparatus according to claim 10, wherein the block part includes polysilicon.

12. The apparatus according to claim 7, wherein the word lines extend across a memory cell array region into the peripheral region, and the word line contacts, the isolation structure, and the block part are in the peripheral region.

13. The apparatus according to claim 12, wherein
the isolation structure is a first isolation structure, and the polysilicon part is a first polysilicon part, and
the apparatus further comprising a second polysilicon part in the memory cell array region between neighboring second isolation structures formed in the semiconductor substrate in the memory cell array region.

14. An apparatus, comprising:
a word line contact coupled to a first word line of neighboring word lines;
a polysilicon part between the neighboring word lines, configured to prevent coupling between the word line contact and a second word line of the neighboring word line.

15. The apparatus according to claim 14, wherein the word lines extend across a memory cell array region into a peripheral region, and the word line contact and the polysilicon part are in the peripheral region.

16. The apparatus according to claim 15, wherein the polysilicon part is embedded in a shallow trench isolation formed in a semiconductor substrate in the peripheral region.

17. The apparatus according to claim 14, wherein the polysilicon part has a pad-like shape between the neighboring word lines.

18. The apparatus according to claim 14, wherein the polysilicon part is adjacent to the word line contact and partially under the word line contact and blocks the word line contact from coming into contact with a conductive part of the second word line.

19. The apparatus according to claim 14, wherein the word line contact remains distant from a conductive part of the second word line.

20. The apparatus according to claim 14, wherein a lower portion of the word line contact is coupled to a conductive part of the first word line and is distant from a conductive part of the second word line.
